(19) United States
(12) Patent Application Publication
(10) Pub. No.: US 2024/0421637 A1
(43) Pub. Date: Dec. 19, 2024

(54) METHOD AND APPARATUS FOR PERFORMING MULTIPLE WIRELESS CHARGING

(71) Applicant: ELECTRONICS AND TELECOMMUNICATIONS RESEARCH INSTITUTE, Daejeon (KR)

(72) Inventors: Seong Min KIM, Daejeon (KR); Gwang Zeen KO, Daejeon (KR); Sang Won KIM, Daejeon (KR); Kye Seok YOON, Daejeon (KR); In Kui CHO, Daejeon (KR)

(21) Appl. No.: 18/668,575

(22) Filed: May 20, 2024

(30) Foreign Application Priority Data
Jun. 16, 2023 (KR) 10-2023-0077708

(51) Int. Cl. H02J 50/12; H02J 7/00; H02J 50/40; H02J 50/80

(52) U.S. Cl. CPC H02J 50/12; H02J 7/0013; H02J 50/402; H02J 50/80; H02J 2207/20

(57) ABSTRACT

The present disclosure relates to a method and apparatus for performing multiple wireless charging. A method or performing wireless charging according to an embodiment of the present disclosure may comprise: identifying one or more receiving coils subject to wireless charging; setting a plurality of transmission frequencies based on a plurality of receiving coils being identified; and transmitting a wireless power transmission signal to the plurality of receiving coils using a plurality of transmitting coils connected to one inverter. Herein, a wireless power transmission signal transmitted from each transmitting coil belonging to the plurality of transmitting coils may be generated by applying the plurality of transmission frequencies in a pre-configured order.

### CROSS-REFERENCE TO RELATED APPLICATIONS

This application claims the benefit of earlier filing date and right of priority to Korean Application No. 10-2023-0077708, filed on Jun. 16, 2023, the contents of which are all hereby incorporated by reference herein in their entirety.

### TECHNICAL FIELD

The present disclosure relates to a method and device for performing multiple/cluster wireless charging.

### BACKGROUND

For existing technology for providing wireless charging for multiple receivers simultaneously, a method of simultaneously charging multiple receiving devices using one transmitting coil or providing wireless charging to each receiving device coupled to each transmitting coil using multiple transmitting coils is mainly used.

In this regard, as a method of simultaneously charging multiple receiving devices using one transmitting coil, a method of providing wireless charging to multiple receiving devices simultaneously using a single transmitting coil larger than the multiple receiving devices may be considered. However, in the case of this method, it is necessary to have a transmitting coil having a larger size than the multiple receiving coils mounted on it, in order for one transmitting coil to transmit power to multiple receiving devices simultaneously.

Additionally, as another method of providing wireless charging using a plurality of transmitting coils, a method of improving the transmission distance by configuring a plurality of transmitting coils in a stack may be considered. However, in the case of this method, the transmission distance of wireless charging may be increased, but there is a problem in maintaining transmission efficiency.

### SUMMARY

The technical object of the present disclosure is to provide a method and device for simultaneously wirelessly charging multiple receivers using one transmitting inverter and multiple transmitting coils.

The technical object of the present disclosure is to provide a method and device for setting the number of transmission frequencies according to the number of receivers subject to wireless charging, and for performing wireless charging by alternately applying transmission frequencies at regular intervals.

The technical objects to be achieved by the present disclosure are not limited to the above-described technical objects, and other technical objects which are not described herein will be clearly understood by those skilled in the pertinent art from the following description.

A method of performing wireless charging according to an aspect of the present disclosure may comprise: identifying one or more receiving coils subject to wireless charging; setting a plurality of transmission frequencies based on the plurality of receiving coils being identified; and transmitting a wireless power transmission signal to the plurality of receiving coils using a plurality of transmitting coils connected to one inverter. Herein, a wireless power transmission signal transmitted from each transmitting coil belonging to the plurality of transmitting coils may be generated by applying the plurality of transmission frequencies in a pre-configured order.

An apparatus for performing wireless charging according to an additional aspect of the present disclosure may comprise a processor and a memory, and the processor may be configured to: identify one or more receiving coils subject to wireless charging; set a plurality of transmission frequencies based on the plurality of receiving coils being identified; and transmit a wireless power transmission signal to the plurality of receiving coils using a plurality of transmitting coils connected to one inverter. Herein, a wireless power transmission signal transmitted from each transmitting coil belonging to the plurality of transmitting coils may be generated by applying the plurality of transmission frequencies in a pre-configured order.

As one or more non-transitory computer readable medium storing one or more instructions according to an additional aspect of the present disclosure, the one or more instructions may be executed by one or more processors and control an apparatus for performing wireless charging to: identify one or more receiving coils subject to wireless charging; set a plurality of transmission frequencies based on the plurality of receiving coils being identified; and transmit a wireless power transmission signal to the plurality of receiving coils using a plurality of transmitting coils connected to one inverter. Herein, a wireless power transmission signal transmitted from each transmitting coil belonging to the plurality of transmitting coils may be generated by applying the plurality of transmission frequencies in a pre-configured order.

In various aspects of the present disclosure, the plurality of transmitting coils may be included in one transmitting device, and each receiving coil belonging to the plurality of receiving coils may be included in a different receiving device.

In addition, in various aspects of the present disclosure, a number of the plurality of transmission frequencies may be set equal to a number of the plurality of receiving coils.

In addition, in various aspects of the present disclosure, each frequency belonging to the plurality of transmission frequencies may be applied during an individually set time interval in accordance with the pre-configured order.

In addition, in various aspects of the present disclosure, a first transmission frequency among the plurality of transmission frequencies may correspond to a center frequency, half of transmission frequencies excluding the first transmission frequency may be located in a low frequency region based on the center frequency, and the other half may be located in a high frequency region based on the center frequency.

In addition, in various aspects of the present disclosure, the plurality of transmission frequencies may be distributed and located within a specific frequency band defined so that a plurality of receiving devices corresponding to the plurality of receiving coils operate.

In addition, in various aspects of the present disclosure, each receiving coil belonging to the plurality of receiving coils may be connected to a matching circuit capable of setting a plurality of matching frequencies according to the plurality of transmission frequencies.

In addition, in various aspects of the present disclosure, transmission of the wireless power transmission signal to the plurality of receiving coils may be performed simultaneously by the one inverter and the plurality of transmitting coils.

In addition, in various aspects of the present disclosure, the plurality of transmitting coils may be connected in parallel to the one inverter.

According to the present disclosure, there is an effect of reducing the amount of electromagnetic radiation that increases as the number of receivers increases, by setting the transmission frequency of the transmission signal according to the number of receivers and transmission signals of each transmission frequency alternately, in order to wirelessly charge multiple receiving coils simultaneously using one inverter and multiple transmitting coils.

According to the present disclosure, in that there is no need to implement additional devices on the transmitter side of wireless charging, since transmitter size, cost, and/or manufacturing time may be reduced, this has the effect of enabling the production of mass-produced products with competitive prices.

Effects achievable by the present disclosure are not limited to the above-described effects, and other effects which are not described herein may be clearly understood by those skilled in the pertinent art from the following description.

### BRIEF DESCRIPTION OF THE DRAWINGS

FIG. 1 illustrates an operational flowchart of a method for performing wireless charging for multiple receiving devices according to an embodiment of the present disclosure.

FIG. 2 illustrates a structure for performing wireless charging for multiple receiving devices according to an embodiment of the present disclosure.

FIG. 3 illustrates a system and transmission signal waveform that perform wireless charging for one receiving device according to an embodiment of the present disclosure.

FIG. 4 illustrates a system and transmission signal waveform that simultaneously performs wireless charging for two receiving devices according to an embodiment of the present disclosure.

FIG. 5A and FIG. 5B illustrate a comparison between the electromagnetic radiation amount of multiple transmission frequencies and the electromagnetic radiation amount of a single transmission frequency according to an embodiment of the present disclosure.

FIG. 6 illustrates a system and transmission signal waveform that simultaneously perform wireless charging for multiple receiving devices according to an embodiment of the present disclosure.

FIG. 7 is a block diagram illustrating a device according to an embodiment of the present disclosure.

### DETAILED DESCRIPTION

As the present disclosure may make various changes and have multiple embodiments, specific embodiments are illustrated in a drawing and are described in detail in a detailed description. But, it is not to limit the present disclosure to a specific embodiment, and should be understood as including all changes, equivalents and substitutes included in an idea and a technical scope of the present disclosure. A similar reference numeral in a drawing refers to a like or similar function across multiple aspects. A shape and a size, etc. of elements in a drawing may be exaggerated for a clearer description. A detailed description on exemplary embodiments described below refers to an accompanying drawing which shows a specific embodiment as an example. These embodiments are described in detail so that those skilled in the pertinent art can implement an embodiment. It should be understood that a variety of embodiments are different each other, but they do not need to be mutually exclusive. For example, a specific shape, structure and characteristic described herein may be implemented in other embodiment without departing from a scope and a spirit of the present disclosure in connection with an embodiment. In addition, it should be understood that a position or an arrangement f an individual element in each disclosed embodiment may be changed without departing from a scope and a spirit of an embodiment. Accordingly, a detailed description described below is not taken as a limited meaning and a scope of exemplary embodiments, if properly described, are limited only by an accompanying claim along with any scope equivalent to that claimed by those claims.

In the present disclosure, a term such as first, second, etc. may be used to describe a variety of elements, but the elements should not be limited by the terms. The terms are used only to distinguish one element from other element. For example, without getting out of a scope of a right of the present disclosure, a first element may be referred to as a second element and likewise, a second element may be also referred to as a first element. A term of and/or includes a combination of a plurality of relevant described items or any item of a plurality of relevant described items.

When an element in the present disclosure is referred to as being “connected” or “linked” to another element, it should be understood that it may be directly connected or linked to that another element, but there may be another element between them. Meanwhile, when an element is referred to as being “directly connected” or “directly linked” to another element, it should be understood that there is no another element between them.

As construction units shown in an embodiment of the present disclosure are independently shown to represent different characteristic functions, it does not mean that each construction unit is composed in a construction unit of separate hardware or one software. In other words, as each construction unit is included by being enumerated as each construction unit for convenience of a description, at least two construction units of each construction unit may be combined to form one construction unit or one construction unit may be divided into a plurality of construction units to perform a function, and an integrated embodiment and a separate embodiment of each construction unit are also included in a scope of a right of the present disclosure unless they are beyond the essence of the present disclosure.

A term used in the present disclosure is just used to describe a specific embodiment, and is not intended to limit the present disclosure. A singular expression, unless the context clearly indicates otherwise, includes a plural expression. In the present disclosure, it should be understood that a term such as “include” or “have”, etc. is just intended to designate the presence of a feature, a number, a step, an operation, an element, a part or a combination thereof described in the present specification, and it does not exclude in advance a possibility of presence or addition of one or more other features, numbers, steps, operations, elements, parts or their combinations. In other words, a description of “including” a specific configuration in the present disclosure does not exclude a configuration other than a corresponding configuration, and it means that an additional configuration may be included in a scope of a technical idea of the present disclosure or an embodiment of the present disclosure.

Some elements of the present disclosure are not a necessary element which performs an essential function in the present disclosure and may be an optional element for just improving performance. The present disclosure may be implemented by including only a construction unit which is necessary to implement essence of the present disclosure except for an element used just for performance improvement, and a structure including only a necessary element except for an optional element used just for performance improvement is also included in a scope of a right of the present disclosure.

Hereinafter, an embodiment of the present disclosure is described in detail by referring to a drawing. In describing an embodiment of the present specification, when it is determined that a detailed description on a relevant disclosed configuration or function may obscure a gist of the present specification, such a detailed description is omitted, and the same reference numeral is used for the same element in a drawing and an overlapping description on the same element is omitted.

The existing method of using one transmitting inverter and multiple transmitting coils was used to connect multiple transmitting coils to one inverter and selectively supply power to the transmitting coil where the receiver is located, for the purpose of supplying wireless power to a receiver in a moving environment. Additionally, a method of using multiple transmitting coils to simultaneously provide wireless charging to multiple receivers is being used in the form of individually supplying power to each transmitting coil using multiple inverters.

In the case of the first method for supplying power in an environment in which the receiver moves, Power may be selectively supplied to only one transmitting coil among multiple transmitting coils, which may cause a problem in which wireless charging can be provided to only one receiver.

Additionally, for the second method to provide wireless charging to multiple receivers simultaneously, problems may arise where the size of the transmitting circuit becomes larger and more complex. Additionally, a method using multiple transmitting coils may cause problems in that transmission power increases as the number of receivers increases, and electromagnetic interference (EMI) increases as transmission power increases.

Considering these problems, the present disclosure proposes a method and device for providing wireless charging to multiple receivers simultaneously using one inverter and multiple transmitting coils.

In this regard, in the method proposed in the present disclosure, a method of adding/setting the number of transmission frequencies to provide wireless charging depending on the number of receivers and reducing electromagnetic radiation (EMI) by changing the transmission frequency at regular intervals is proposed. Through this, a technical effect may be derived that reduces the amount of electromagnetic radiation that increases as the number of receivers increases.

In other words, in the present disclosure, a method of adding transmission frequencies and transmitting across each transmission frequency, when selecting the number of transmission frequencies appropriate for the number of receivers and the number of receivers increases, rather than performing wireless charging using only a single frequency (e.g., f₁) as in the past.

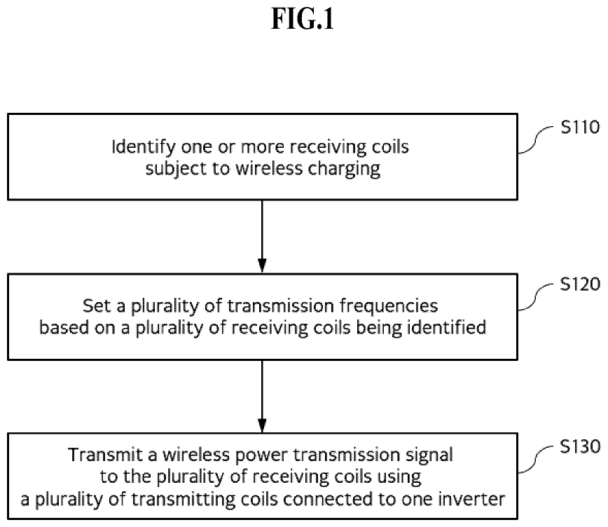

FIG. 1 illustrates an operational flowchart of a method for performing wireless charging for multiple receiving devices according to an embodiment of the present disclosure.

In step S110, one or more receiving coils that are the target of wireless charging may be identified.

For example, the method described in FIG. 1 may be for simultaneously wirelessly charging multiple receiving coils, that is, multiple receivers.

If a plurality of receiving coils are identified in step S110, a plurality of transmission frequencies may be set in step S120.

Here, multiple transmission frequencies may mean multiple frequencies set by the transmitter to transmit wireless power. As an example, the frequency may correspond to a resonance frequency according to a matching circuit connected to the transmitting coil of the transmitter.

In step S130, a wireless power transmission signal may be transmitted to a plurality of receiving coils using a plurality of transmitting coils connected to one inverter.

Here, the wireless power transmission signal transmitted from each transmitting coil belonging to the plurality of transmitting coils may be generated by applying the plurality of transmission frequencies in step S120 in a pre-configured order.

In this regard, a plurality of transmitting coils are included/implemented in one transmitting device, and each receiving coil belonging to a plurality of receiving coils may be included/implemented in a different receiving device.

Additionally or alternatively, the number of transmission frequencies set in step S120 may be set equal to the number of receiving coils identified in step S110.

Additionally or alternatively, each frequency belonging to the plurality of transmission frequencies may be applied during an individually set time interval in accordance with the pre-configured order. That is, multiple transmission frequencies may be alternately transmitted by each transmitting coil.

Additionally or alternatively, a first transmission frequency among multiple transmission frequencies may correspond to a center frequency. At this time, half of the transmission frequencies excluding the first transmission frequency may be located in a low frequency region based on the center frequency, and the other half may be located in a high frequency region based on the center frequency.

Additionally or alternatively, a plurality of transmission frequencies may be distributed and located within a specific frequency band defined for operation of a plurality of receiving devices corresponding to the plurality of receiving coils and/or a transmitting device including/implementing a plurality of transmitting coils.

Additionally or alternatively, each receiving coil belonging to the multiple receiving coils may be connected to a matching circuit (e.g., variable matching circuit) capable of setting multiple matching frequencies according to multiple transmission frequencies.

Additionally or alternatively, transmission of the wireless power transmission signal in step S130 to a plurality of receiving coils may be performed simultaneously by one inverter and a plurality of transmitting coils.

Additionally or alternatively, multiple transmitting coils may be designed to be connected in parallel to one inverter.

Hereinafter, considering the operation described in FIG. 1, the wireless charging method and device proposed in the present disclosure will be described in detail.

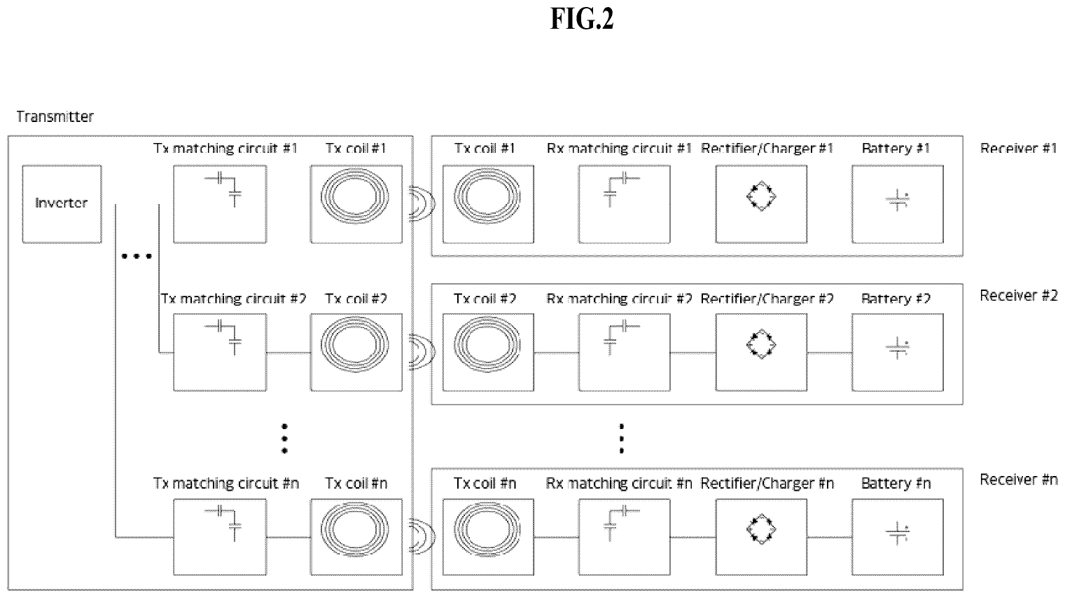

FIG. 2 illustrates a structure for performing wireless charging for multiple receiving devices according to an embodiment of the present disclosure.

A device for simultaneously charging multiple receivers may be constructed using one inverter, multiple transmitting coils, and a fixed transmission matching circuit.

Specifically, The transmitter of FIG. 2 may be composed of an inverter for driving multiple transmitting coils, multiple transmitting coils for simultaneously charging multiple receivers, and a matching circuit connected to each transmitting coil.

According to an embodiment of the present disclosure, each transmitting coil and matching circuit may be connected and driven in parallel to one inverter.

In particular, the matching circuit connected to each transmitting coil may be configured such that the matching value resonates at the transmission frequency of each transmitting coil.

In other words, for the first matching circuit (i.e., transmission matching circuit #1) connected to the first transmitting coil (i.e., transmitting coil #1), the matching value may be set to resonate at the transmission frequency (f₁). For the second matching circuit (i.e., transmission matching circuit #2) connected to the second transmitting coil (i.e., transmitting coil #2), the matching value may be set to resonate at the transmission frequency (f₂). According to this principle, for the n^{th} matching circuit (i.e., transmission matching circuit #n) connected to the n^{th} transmitting coil (i.e., transmitting coil #n), the matching value may be set to resonate at the transmission frequency (fₙ).

According to an embodiment of the present disclosure, the wireless charging transmitter of FIG. 2 may use a plurality of transmitting coils to transmit wireless power to a receiver equipped with a plurality of reception coils.

In this regard, in the existing case, in order to wirelessly charge multiple receivers using multiple transmitting coils, a method of simultaneously transmitting wireless power using one transmission frequency from one inverter was used. In this way, when multiple receivers are charged simultaneously using one transmission frequency, As the number of receivers increases, transmission power increases, and as transmission power increases, electromagnetic radiation also increases.

Therefore, in order to reduce the transmission power and electromagnetic radiation that increases depending on the number of receivers as described above, a method of alternating transmission frequencies appropriate for the number of receivers being simultaneously charged is proposed in the present disclosure.

In other words, in order to simultaneously charge multiple receivers using one transmitter, the transmitter may transmit n transmission frequency signals (i.e., signals with f₁ to fₙ) alternating with time. At this time, each receiver may receive power using n transmission frequency signals (i.e., signals having f₁ to fₙ) transmitted crosswise, and may charge the battery corresponding to the load.

At this time, in order to maximize the transmission efficiency of wireless power, the reception matching circuit of each receiver may set the matching frequency to match the transmitted frequency. To this end, if each receiver contains a variable matching circuit, or a fixed matching circuit, each receiver may perform charging by being located at a transmitting coil corresponding to the transmission frequency.

For example, when the receiver performs charging in close proximity to the first transmitting coil, a receiver equipped with a variable matching circuit may set the matching frequency of the reception matching circuit to match f₁. Alternatively, for a receiver with a fixed matching circuit matched to f₁, the receiver may be induced to charge by being close to the first transmitting coil that transmits a signal according to the transmission frequency f₁.

Hereinafter, the present disclosure will specifically describe a method of performing wireless charging by setting multiple transmission frequencies to simultaneously charge multiple receivers.

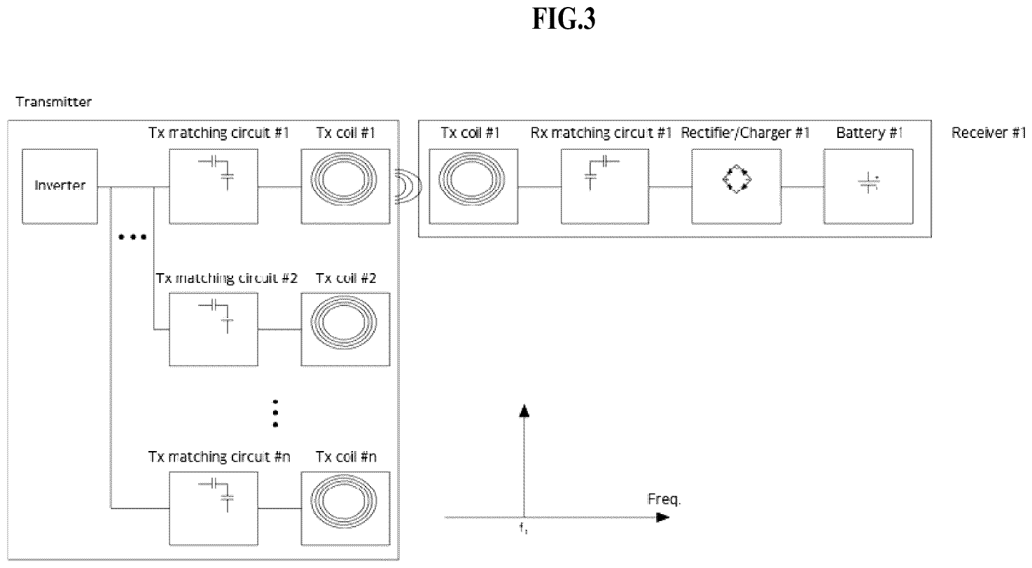

FIG. 3 illustrates a system and transmission signal waveform that perform wireless charging for one receiving device according to an embodiment of the present disclosure.

Referring to FIG. 3, a case of charging one receiver using a cluster/multiple wireless charging device that simultaneously charges multiple receivers is illustrated.

The transmission signal waveform corresponding to f₁ in the frequency domain shown in FIG. 3 exemplifies the transmission signal waveform when charging one receiver.

For example, when the first reception coil shown in FIG. 3 approaches the first transmitting coil shown in FIG. 3, and there is no reception coil in the second transmitting coil, the transmitter may set one transmission frequency (f₁) to charge one receiver, and perform wireless power transmission based on this.

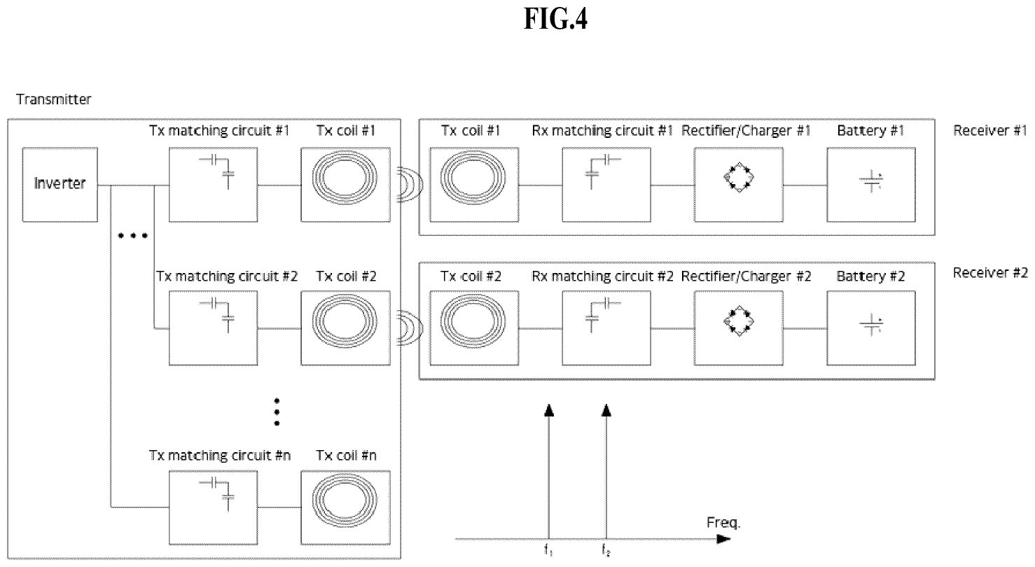

FIG. 4 illustrates a system and transmission signal waveform that simultaneously performs wireless charging for two receiving devices according to an embodiment of the present disclosure.

Referring to FIG. 4, a case in which two receivers simultaneously charged using a cluster/multiple wireless are charging device that simultaneously charges multiple receivers is illustrated.

The transmission signal waveforms corresponding to f₁ and f₂ in the frequency domain shown in FIG. 4 illustrate transmission signal waveforms that are alternately transmitted to simultaneously charge two receivers.

For example, when the first reception coil approaches the first transmitting coil and the second reception coil approaches the second transmitting coil, the transmitter may set two transmission frequencies f₁ and f₂ and alternately transmit signals based on the two transmission frequencies.

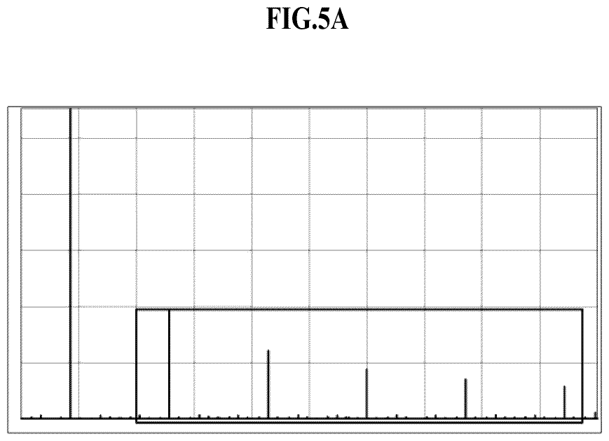

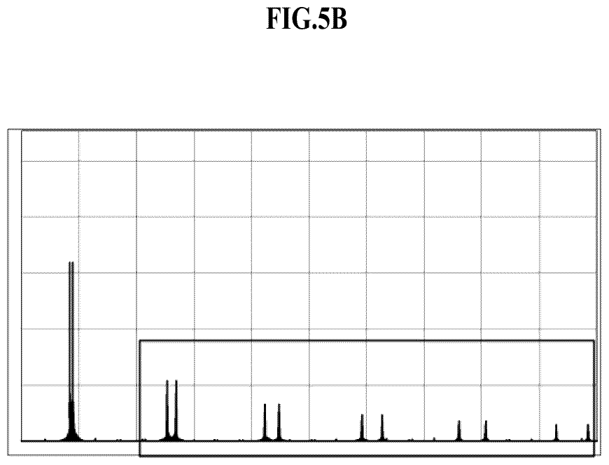

FIG. 5 illustrates a comparison between the electromagnetic radiation amount of multiple transmission frequencies and the electromagnetic radiation amount of a single transmission frequency according to an embodiment of the present disclosure.

FIG. 5A illustrates the amount of electromagnetic radiation when two receivers are simultaneously charged using a single frequency.

FIG. 5B illustrates the amount of electromagnetic radiation when two receivers are simultaneously charged by alternately transmitting signals at two transmission frequencies according to the method proposed in the present disclosure.

Comparing FIG. 5A and FIG. 5B, compared to charging two receivers simultaneously using a single frequency, it may be confirmed that the amount of electromagnetic wave radiation is lowered when two receivers are simultaneously charged by alternately transmitting signals of two transmission frequencies.

Therefore, it can be confirmed that the method proposed in the present disclosure is effective in reducing the amount of electromagnetic radiation.

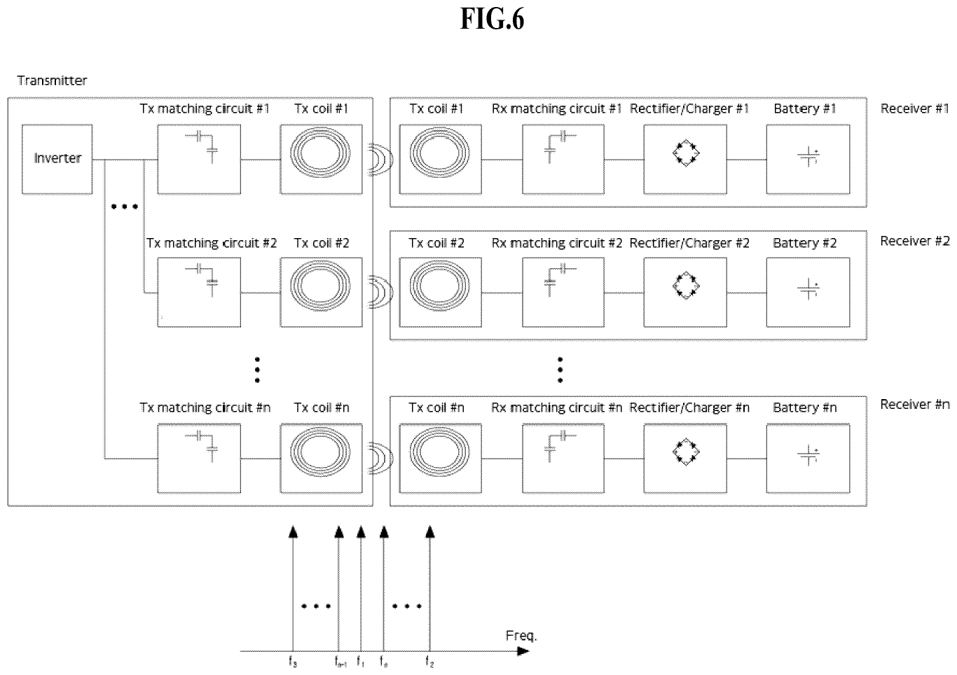

FIG. 6 illustrates a system and transmission signal waveform that simultaneously perform wireless charging for multiple receiving devices according to an embodiment of the present disclosure.

Referring to FIG. 6, a system configuration and transmission signal waveform for simultaneously charging n receivers (where n is an integer greater than or equal to 1) are illustrated.

As shown in FIG. 6, in order to charge n receivers simultaneously, the transmitter may set n transmission frequencies (i.e., f₁ to fₙ) and may repeatedly transmit signals at each transmission frequency across a certain period of time. That is, the number of receivers and the number of transmission frequencies are set to be the same.

In this regard, n transmission frequencies may be set in a manner that crosses in both directions with f₁ as the center frequency. Through this, the effect of n transmission frequencies being set on a certain band based on the center frequency may occur.

A method of setting n transmission frequencies to simultaneously charge n receivers and alternately transmitting signals based on the set n transmission frequencies may reduce transmission power and electromagnetic radiation which are increased by simultaneously charging n receivers.

At this time, a receiver coupled to/close to each transmitting coil may be configured to match the transmission frequency transmitted from each transmitting coil.

For example, if each receiver is equipped with/includes a variable matching circuit, the receiver may adjust the matching frequency of the variable matching circuit to match the transmission frequency of the coupled transmission coil. Alternatively, if each receiver is equipped/includes a fixed matching circuit, charging may be induced by coupling the receiver to the transmitting coil corresponding to the matched frequency.

As described above in the present disclosure, to simultaneously charge multiple receivers using one transmitter and multiple transmitting coils, the same number of transmission frequencies as the number of receivers is set, and the transmitter may cross-transmit signals of the set transmission frequencies. Through this, the amount of transmission power and electromagnetic wave radiation that increases as the number of simultaneously charging receivers increases may be reduced.

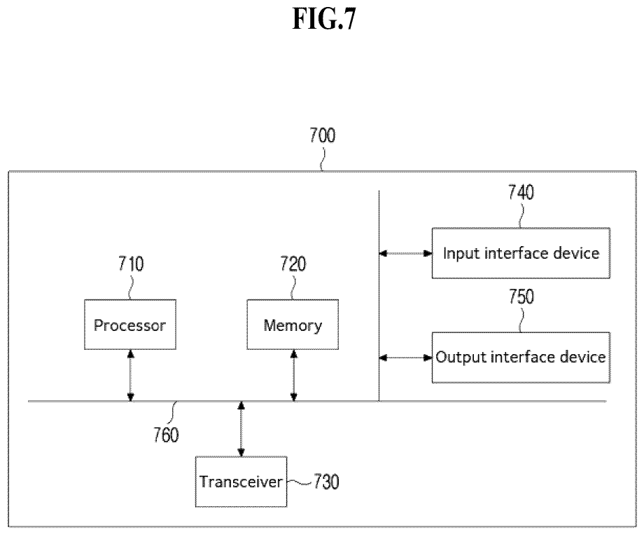

FIG. 7 is a block diagram illustrating an apparatus according to an embodiment of the present disclosure.

Referring to FIG. 7, device 700 may represent a device that implements the method of simultaneously wirelessly charging multiple receivers using one inverter and multiple transmitting coils described in the present disclosure.

For example, the device 700 may generally support/perform a function to set the transmission frequency according to the number of receivers subject to wireless charging, a function to alternately and repeatedly transmit signals of a set transmission frequency, etc.

The device 700 may include at least one of a processor 710, a memory 720, a transceiver 730, an input interface device 740, and an output interface device 750. Each of the components may be connected by a common bus 760 to communicate with each other. In addition, each of the components may be connected through a separate interface or a separate bus centering on the processor 710 instead of the common bus 760.

The processor 710 may be implemented in various types such as an application processor (AP), a central processing unit (CPU), a graphic processing unit (GPU), etc., and may be any semiconductor device that executes a command stored in the memory 720. The processor 710 may execute a program command stored in the memory 720. The processor 710 may be configured to implement a method/system of simultaneously wirelessly charging multiple receivers using one inverter and multiple transmitting coils based on FIGS. 1 to 6 described above.

And/or, the processor 710 may store a program command for implementing at least one function for the corresponding modules in the memory 720 and may control the operation described based on FIGS. 1 to 6 to be performed.

The memory 720 may include various types of volatile or non-volatile storage media. For example, the memory 720 may include read-only memory (ROM) and random access memory (RAM). In an embodiment of the present disclosure, the memory 720 may be located inside or outside the processor 710, and the memory 720 may be connected to the processor 710 through various known means.

The transceiver 730 may perform a function of transmitting and receiving data processed/to be processed by the processor 710 with an external device and/or an external system.

The input interface device 740 is configured to provide data to the processor 710.

The output interface device 750 is configured to output data from the processor 710.

According to the present disclosure, there is an effect of reducing the amount of electromagnetic radiation that increases as the number of receivers increases, by setting the transmission frequency of the transmission signal according to the number of receivers and transmission signals of each transmission frequency alternately, in order to wirelessly charge multiple receiving coils simultaneously using one inverter and multiple transmitting coils.

In addition, according to the present disclosure, in that there is no need to implement additional devices on the transmitter side of wireless charging, since transmitter size, cost, and/or manufacturing time may be reduced, this has the effect of enabling the production of mass-produced products with competitive prices.

The components described in the example embodiments may be implemented by hardware components including, for example, at least one digital signal processor (DSP), a processor, a controller, an application-specific integrated circuit (ASIC), a programmable logic element, such as an FPGA, GPU other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., programmable processor, a computer, or multiple computers.

A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors. Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment.

Features described in the specification in the context of individual example embodiments may be implemented as a combination in a single example embodiment. In contrast, various features described in the specification in the context of a single example embodiment may be implemented in multiple individually or in an appropriate sub-example embodiments combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Accordingly, it is intended that this disclosure embrace all other substitutions, modifications and variations belong within the scope of the following claims.

What is claimed is:

1. A method of performing wireless charging, the method comprising:
identifying one or more receiving coils subject to wireless charging;
setting a plurality of transmission frequencies based on a plurality of receiving coils being identified; and
transmitting a wireless power transmission signal to the plurality of receiving coils using a plurality of transmitting coils connected to one inverter,
wherein a wireless power transmission signal transmitted from each transmitting coil belonging to the plurality of transmitting coils is generated by applying the plurality of transmission frequencies in a pre-configured order.

2. The method of claim 1,
wherein the plurality of transmitting coils are included in one transmitting device, and
wherein each receiving coil belonging to the plurality of receiving coils is included in a different receiving device.

3. The method of claim 1,
wherein a number of the plurality of transmission frequencies is set equal to a number of the plurality of receiving coils.

4. The method of claim 1,
wherein each frequency belonging to the plurality of transmission frequencies is applied during an individually set time interval in accordance with the pre-configured order.

5. The method of claim 1,
wherein a first transmission frequency among the plurality of transmission frequencies corresponds to a center frequency,
wherein half of transmission frequencies excluding the first transmission frequency are located in a low frequency region based on the center frequency, and
wherein the other half are located in a high frequency region based on the center frequency.

6. The method of claim 1,
wherein the plurality of transmission frequencies are distributed and located within a specific frequency band defined so that a plurality of receiving devices corresponding to the plurality of receiving coils operate.

7. The method of claim 1,
wherein each receiving coil belonging to the plurality of receiving coils is connected to a matching circuit capable of setting a plurality of matching frequencies according to the plurality of transmission frequencies.

8. The method of claim 1,
wherein transmission of the wireless power transmission signal to the plurality of receiving coils is performed simultaneously by the one inverter and the plurality of transmitting coils.

9. The method of claim 1,
wherein the plurality of transmitting coils are connected in parallel to the one inverter.

10. An apparatus for performing wireless charging, the apparatus comprising:
a processor and a memory,
wherein the processor is configured to:
identify one or more receiving coils subject to wireless charging;
set a plurality of transmission frequencies based on a plurality of receiving coils being identified; and
transmit a wireless power transmission signal to the plurality of receiving coils using a plurality of transmitting coils connected to one inverter,
wherein a wireless power transmission signal transmitted from each transmitting coil belonging to the plurality of transmitting coils is generated by applying the plurality of transmission frequencies in a pre-configured order.

11. The apparatus of claim 10,
wherein the plurality of transmitting coils are included in one transmitting device, and
wherein each receiving coil belonging to the plurality of receiving coils is included in a different receiving device.

12. The apparatus of claim 10,
wherein a number of the plurality of transmission frequencies is set equal to a number of the plurality of receiving coils.

13. The apparatus of claim 10,
wherein each frequency belonging to the plurality of transmission frequencies is applied during an individually set time interval in accordance with the pre-configured order.

14. The apparatus of claim 10,
wherein a first transmission frequency among the plurality of transmission frequencies corresponds to a center frequency,
wherein half of transmission frequencies excluding the first transmission frequency are located in a low frequency region based on the center frequency, and
wherein the other half are located in a high frequency region based on the center frequency.

15. The apparatus of claim 10,
wherein the plurality of transmission frequencies are distributed and located within a specific frequency band defined so that a plurality of receiving devices corresponding to the plurality of receiving coils operate.

16. The apparatus of claim 10,
wherein each receiving coil belonging to the plurality of receiving coils is connected to a matching circuit capable of setting a plurality of matching frequencies according to the plurality of transmission frequencies.

17. The apparatus of claim 10,
wherein transmission of the wireless power transmission signal to the plurality of receiving coils is performed simultaneously by the one inverter and the plurality of transmitting coils.

18. The apparatus of claim 10,
wherein the plurality of transmitting coils are connected in parallel to the one inverter.

19. One or more non-transitory computer readable medium storing one or more instructions,
wherein the one or more instructions are executed by one or more processors and control an apparatus for performing wireless charging to:
identify one or more receiving coils subject to wireless charging;
set a plurality of transmission frequencies based on a plurality of receiving coils being identified; and
transmit a wireless power transmission signal to the plurality of receiving coils using a plurality of transmitting coils connected to one inverter,
wherein a wireless power transmission signal transmitted from each transmitting coil belonging to the plurality of transmitting coils is generated by applying the plurality of transmission frequencies in a pre-configured order.

20. The computer readable medium of claim 19,
wherein a number of the plurality of transmission frequencies is set equal to a number of the plurality of receiving coils.
